(19) United States
(12) Patent Application Publication
(10) Pub. No.: US 2011/0110173 A1
(43) Pub. Date: May 12, 2011

(54) SIGNAL GENERATING CIRCUIT AND RELATED STORAGE APPARATUS

(76) Inventors: Hung-Chih Chang, Yilan County (TW); Ming-Tsung Li, Tainan City (TW); Chen-Jung Lee, Hsinchu County (TW); Che-Hung Lai, Changhua County (TW)

(21) Appl. No.: 12/717,141

(22) Filed: Mar. 4, 2010

(30) Foreign Application Priority Data
Nov. 11, 2009 (TW) 098138229

(51) Int. Cl. G11C 7/00; G11C 5/14; G06F 12/00; G06F 12/02

(52) U.S. Cl. 365/191; 365/226; 711/154; 711/103; 711/E12.001; 711/E12.008

(57) ABSTRACT

A signal generating circuit is employed for generating a control in order to control operations of one of a controller and at least a storage unit of a related storage apparatus controlled by the controller. The signal generating circuit includes a voltage inputting unit and a voltage detection unit. The voltage detection unit rapidly switches a voltage level of the control signal according to a voltage to be detected which is generated by the voltage inputting unit. As a result, data damage due to unexpected operations performed by the controller during the power-off period can be avoided.

### BACKGROUND OF THE INVENTION

1. Field of the Invention

The present invention relates to a signal generating circuit, and more particularly, to a signal generating circuit mainly based on a voltage detecting circuit utilized for accelerating the signal level switching of a control signal for a controller in a storage apparatus in order to provide write protection for the data stored in the storage apparatus.

2. Description of the Prior Art

Please refer to FIG. 1, in which a block diagram of a conventional controller applied to a storage device is shown. As shown in the diagram, a storage apparatus 100 includes a controller 110 and a flash memory 120. A reset control terminal RST# of the controller 100 is coupled to a resistor R and a capacitor C, wherein one terminal of the resistor R is coupled to a power supplying terminal V_{DD} of a power source (not shown) in the storage unit 100, and one terminal of the capacitor C is coupled to a ground terminal GND in the storage device 100. After power-on, the power supplying terminal V_{DD} supplies power to the resistor R. A voltage level on the reset control terminal RST# of the controller 100 is therefore asserted to a logical high level “1”. At this moment, the controller 110 is allowed to perform a data read operation or data write operation upon the flash memory 120. Furthermore, once the power source of the storage apparatus 100 is shut down, the power supplying terminal V_{DD} no longer supplies the power to the resistor R so that the voltage level on the reset control terminal RST# is discharged through the ground GND, thereby gradually decreasing to a logical low level “0”. As a result, the controller 110 is unable to perform any write/read operation upon the flash memory 120.

During the period in which the voltage level on the reset control signal RST# gradually decreases to the logical low level “0”, the voltage level of the power supplied to the controller 110 may still be within the operating voltage range of the controller 110. Under this condition, the controller 110 is probably able to perform write/read operations upon the flash memory 120. However, as the voltage level of the power provided to the controller 110 is very close to the margin of the operating voltage range, it is possible to cause the controller 110 to perform a false operation upon the flash memory 120 due to noise existing in the circuitry. In the worst case, data stored in the flash memory 120 may be damaged, changed, or erased by the controller 110, or the controller 110 may write faulty data into the flash memory 120.

If the boot configuration data of the operating system is stored in the storage apparatus 100, the above-mentioned false operation may further result in damage to the boot configuration data so that the operating system will be unable to be loaded. As demonstrated by this example, there are still certain problems existing in the conventional art that need to be solved.

### SUMMARY OF THE INVENTION

With this in mind, it is one objective of the present invention to prevent unexpected control and access to the flash memory from being performed by the controller due to instability in the power-off period. The present invention greatly reduces a possible period in which false operations performed by the controller may occur while powering off. As a result, the stability and reliability of the storage apparatus can be improved.

According to one exemplary embodiment of the present invention, a signal generating circuit is provided. The signal generating circuit is employed for generating a control signal in order to control operations of at least one of a controller and at least one storage unit controlled by the controller in a storage apparatus. The signal generating circuit includes a voltage inputting unit and a voltage detecting unit. The voltage inputting unit is coupled to a power supplying terminal, and utilized for generating a voltage to be detected according to a voltage level of supply power received at the power supplying terminal. The voltage detecting unit has an input terminal and an output terminal, and the input terminal is coupled to the voltage inputting unit while the output terminal is coupled to at least one of the control terminals of the controller and the storage unit. In addition, the voltage detecting unit is utilized for comparing a predetermined voltage threshold with the voltage to be detected so as to generate the control signal. The voltage detecting unit generates the control signal having a first logic level so that the controller is unable to perform a write operation upon the storage unit when the voltage to be detected is lower than the predetermined voltage threshold, and generates the control signal having a second logic level so that the controller is able to perform a write operation upon the storage unit when the voltage to be detected is not lower than the predetermined voltage threshold.

Based on the above mentioned exemplary signal generating circuit, a storage apparatus is further provided by the present invention. The storage apparatus includes at least one storage unit, a controller and a signal generating circuit. The storage unit is utilized for storing data. The controller is coupled to the storage unit, and utilized for performing write and read operations upon the storage unit. The signal generating circuit is utilized for generating a control signal to control operations of at least one of the controller and the storage unit. The signal generating circuit includes a voltage inputting unit and a voltage detecting unit. The voltage inputting unit is coupled to a power supplying terminal, and utilized for generating a voltage to be detected according to a voltage level of supply power received at the power supplying terminal. The voltage detecting unit has an input terminal and an output terminal, and the input terminal is coupled to the voltage inputting unit while the output terminal is coupled to at least one of the control terminals of the controller and the storage unit. The signal generating circuit is utilized for comparing a predetermined voltage threshold with the voltage to be detected so as to generate the control signal, wherein the voltage detecting unit generates the control signal having a first logic level so that the controller is unable to perform a write operation upon the storage unit when the voltage to be detected is lower than the predetermined voltage threshold, and generates the control signal having a second logic level so that the controller is able to perform a write operation upon the storage unit when the voltage to be detected is not lower than the predetermined voltage threshold.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a conventional controller applied to a flash memory.

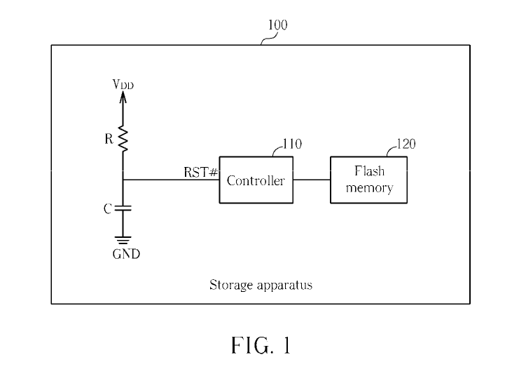

FIG. 2 is a block diagram of an inventive signal generating circuit applied to a storage apparatus according to a first exemplary embodiment of the present invention.

FIG. 3 is a block diagram of an inventive signal generating circuit applied to a storage apparatus according to a second exemplary embodiment of the present invention.

FIG. 4 is a block diagram of an inventive signal generating circuit applied to a storage apparatus according to a third exemplary embodiment of the present invention.

FIG. 5 is a block diagram of an inventive signal generating circuit applied to a storage apparatus according to a fourth exemplary embodiment of the present invention.

### DETAILED DESCRIPTION

According to one exemplary embodiment of the present invention, a signal generating circuit utilizes a supply power voltage level of a power source in the storage apparatus detected by a voltage detecting unit to generate a control signal which can be rapidly switched between different logic levels. When the storage apparatus is turned off and the supply power voltage level deceases, the signal generating circuit accordingly adjust the logic level of the control signal, reconfiguring the control signal on the reset control terminal of the controller to prevent false operations of the controller.

Furthermore, in the exemplary embodiments of the present invention, an additional protection mechanism is utilized for data stored in the data apparatus to prevent data damage caused by the false operations. The additional protection mechanism utilizes write protection terminals of storage units in the storage apparatus to perform protection by synchronizing control signals on the write protection terminals with the reset control signal on the reset control terminal of the controller. In other words, when the voltage level of the control signal on the reset control terminal decreases to a logical low level while the power is turned off, the signal generating circuit can immediately switch a voltage level of the control signals on the write protection terminals down to the logical low level, preventing the data stored in the storage units from being unexpectedly changed or damaged by possible false operations.

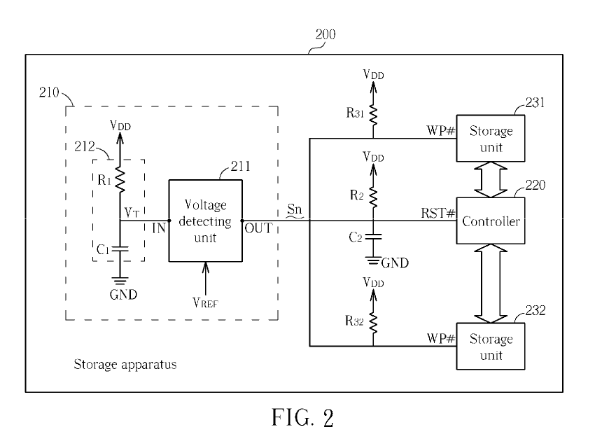

Please refer to FIG. 2, which illustrates a diagram of a first exemplary embodiment of the inventive signal generating circuit. As shown in FIG. 2, a signal generating circuit 210 is applied to a storage apparatus 200. In addition to the signal generating circuit 210, the storage apparatus 200 further includes a controller 220 and a plurality of storage units (e.g. storage units 231 and 232). The controller 220 is mainly utilized for controlling access to the storage units 231 and 232. The signal generating circuit 210 generates a control signal Sn, which is transmitted respectively to a reset control terminal RST# of the controller 220 and write protection terminals WP# of the storage units 231 and 232. The reset control terminal RST# of the controller 220 is coupled to a resistor R2 and a capacitor C2. The resistor R2 and the capacitor C2 are respectively coupled to a supply power having a voltage level of V_{DD} and a ground terminal as shown in FIG. 2. Additionally, the write protection terminals WP# of the storage units 231 and 232 are coupled to the supply power having a voltage level of V_{DD} through the resistors R31 and R32, respectively.

By means of controlling the logic level switching of the control signal Sn, the signal generating circuit 210 can control operations of the controller 220 and the storage units 231 and 232 in the storage apparatus 200. Since the main concept of the present invention is to prevent the false operations caused by the controller 220 while the power of the storage apparatus 200 is being shut down, the present invention utilizes the signal generating circuit 210 to accelerate the signal level switching on the reset control terminal RST# of the controller 220, thereby reducing the possibility of the occurrence of false operations. Furthermore, in this exemplary embodiment, an additional protection mechanism is introduced upon the storage units 231 and 231 by sending the control signal Sn to the write protection terminals WP# of the storage units 231 and 232. In the meantime, the control signal Sn of the signal generating circuit 210 is gradually pulled down to logical low level “0”, placing the controller 220 in the reset state. Thus, the controller 220 is unable to perform any operations. The storage units 231 and 232 are also under write protection due to the switching of the control signal so that no data is allowed to be written into the storage units 231 and 232. Hence, even if the controller 220 intends to perform false operations upon the storage units 231 and 232, e.g. unexpectedly overwriting or erasing data stored in the storage units 231 and 232 due to unstable supply power, the control signal on the write protection terminal WP# on the logical low level “0” makes data stored in the storage units 231 and 232 unable to be overwritten or erased.

In one exemplary embodiment of the present invention, the storage apparatus 200 may be a dual-channel solid state drive, the controller 220 may be a flash memory controller, and the storage units 231 and 232 may be flash memory chips. However, this is just an illustrative case rather than a limitation of the present invention in order for the reader to clearly understand how to render this invention. Broadly, the main spirit of the present invention is to utilize a signal generating circuit to accelerate the signal level switching of the reset control signal of the controller as well as to place the storage units under write protection so that the unexpected data damage can be avoided. Those skilled in the art should be able to carry out the present invention with any other type of storage units while retaining the teaching of the present invention. These modifications also fall within the scope of the present invention.

In the embodiment shown in FIG. 2, the signal generating circuit 210 includes a voltage detecting unit 211 and a voltage inputting unit 212. The voltage inputting unit is coupled to a power supplying terminal supplying the power having the voltage level of V_{DD}, and outputs a voltage to be detected V_{T} according to the voltage level V_{DD}, wherein the power at the power supplying terminal is provided by a regulator (not shown in FIG. 2). The voltage detecting unit 211 has an input terminal IN and an output terminal OUT. The input terminal IN is coupled to the voltage inputting unit 212, and the output terminal OUT is coupled to the reset control terminal RST# of the controller 220 and the write protection terminals WP# of the storage units 231 and 232. The voltage detecting unit 211 is utilized for accelerating the signal level switching of the reset control signal for the controller 220 by means of comparing a predetermined voltage threshold V_{REF} with the voltage to be detected V_{T} for generating the control signal Sn. As the voltage detecting unit 212 can directly respond to the voltage level of the voltage to be detected V_{T} on the input terminal IN, by coupling the output terminal OUT to the reset control terminal RST# of the controller 220, the reconfiguration of the control signal on the reset control terminal RST# can be accelerated.

For example, assuming that the operating voltage of the controller 220 is around 3.3V (which is identical to the voltage level V_{DD} of the supply power) and the predetermined voltage threshold V_{REF} is configured as 2.7V, once the power is shut down, the voltage level of the supply power gradually decreases from 3.3V, causing the voltage level of the voltage to be detected V_{T} to be lower than 2.7V. The voltage detecting unit 211 then outputs the control signal having the logical low level “0” so that the controller 220 cannot perform a write operation or an erase operation upon the storage units 231 and 232; otherwise, when the power is normally supplied, the voltage to be detected V_{T} will not be lower than the predetermined voltage threshold V_{REF}. As a result, the voltage detecting unit 211 constantly outputs the control signal Sn having the logical high level “1” to allow the controller 220 to perform read/write operations upon the storage units 231 and 232. Furthermore, as the output terminal OUT of the voltage detecting unit 211 is respectively coupled to the write protection terminals WP# of the storage units 231 and 232, the signal generating circuit 210 can make the signal level switching on write protection terminals WP# synchronized with the signal level switching on the reset control terminal RST# while the power is shut down. Subsequently, the data stored in the storage units 231 and 232 can be protected from being overwritten or erased by the unexpected false operations.

In this exemplary embodiment, the voltage inputting unit 212 includes a resistor R1 and a capacitor C1, so the voltage inputting unit 212 not only can generate the voltage to be detected V_{T} according to the voltage level V_{DD} provided by the supply power, but also can control the rising time of the voltage to be detected V_{T} according to a time constant determined by the selection of the resistance and the capacitance. This design intends to avoid the condition where the control signal on the reset control terminal RST# of the controller 220 is wrongly configured to place the controller 220 in a normal operating state while other circuit components do not operate steadily due to the too fast rising of the voltage level of the control signal Sn when the power has just been turned on. Thus, by properly choosing the time constant determined by the resistor R1 and the capacitor C1 and the time constant determined by the resistor R2 and the capacitor C2, the rising time of the control signal Sn will become steady, thereby making the timing of configuring the reset control signal of the controller 220 consistent with the timing of stabilizing other circuit components inside the controller 220. The supply power having the voltage level V_{DD} is also coupled to the storage units 231 and 232 via the resistors R31 and R32, which can assert the signal level on the write protection terminal WP# to the logical high level “1” while the power is normally supplied so that the storage units 231 and 232 can be accessed. It should be noted that the above-mentioned logical level utilized is just one of a number of possible implementations rather than a limitation of the present invention. Thus, in an alternative implementation, it is also possible to utilize inversed logical levels (i.e., an active low logic level) compared to the above-mentioned active high logic level to achieve the same effect.

In the following, more exemplary embodiments are provided for illustrating the spirit of the present invention. For the sake of brevity, circuit components labeled with the same numberings as the above exemplary embodiments have similar functions and operations, and will not be described again.

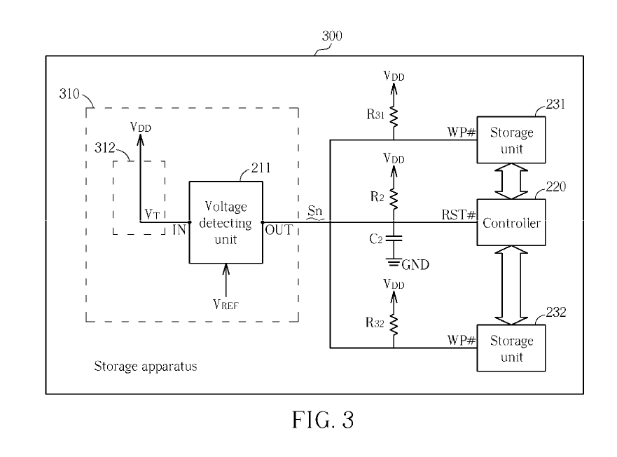

Please refer to FIG. 3, which depicts a block diagram of an inventive signal generating circuit applied in a storage apparatus according to a second exemplary embodiment of the present invention. As shown in FIG. 3, another possible implementation is given, in which a supply power of a storage apparatus 300 is directly provided to the input terminal IN of the voltage detecting unit 211. In this, the signal generating circuit 211 directly utilizes the voltage level V_{DD} provided by the supply power as the voltage to be detected V_{T} to generate the control signal Sn for respectively controlling the controller 220 and the storage units 231 and 232. That is, the voltage inputting unit 312 is implemented with a piece of conducting wire. Apart from this, operations of the voltage detecting unit 211 in the signal generating circuit 310 are identical to the voltage detecting unit 211 in the signal generating circuit 210 shown in FIG. 2.

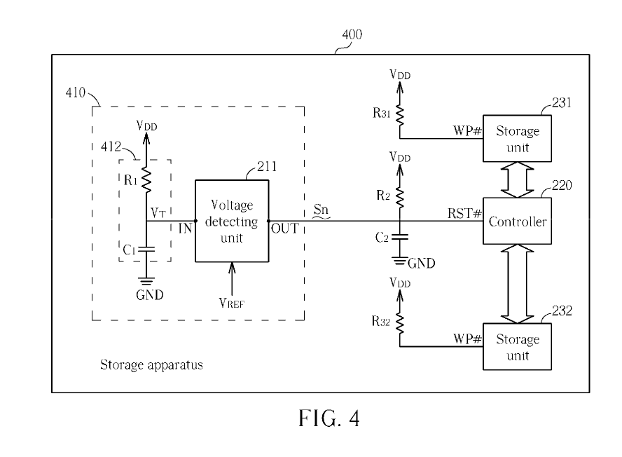

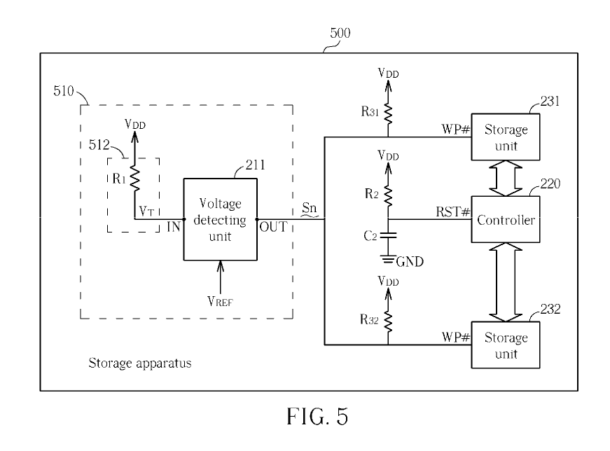

Furthermore, in other exemplary embodiments of the present invention, the inventive signal generating circuit may control only one of the controller and the storage unit, providing more flexibility for applications. Please refer to FIG. 4 and FIG. 5, each of which depicts a different exemplary embodiment of the inventive signal generating circuit. FIG. 4 shows a third exemplary embodiment of the inventive signal generating circuit, in which the inventive signal generating circuit 410 outputs control signal Sn to the controller 220 for protecting the storage apparatus 400 instead of outputting the control signal Sn to the storage units 231 and 232. FIG. 5 shows a fourth exemplary embodiment of the inventive signal generating circuit, in which the inventive signal generating circuit 510 outputs control signal Sn to the storage units 231 and 232 for protecting the storage apparatus 500 instead of outputting the control signal Sn to the controller 220. In addition, the voltage inputting unit 512 in the signal generating circuit 510 is rendered with a resistor R1 as compared to the resistor R1 and capacitor C1 of the voltage inputting unit 412 in the signal generating circuit 410. Both of the above exemplary embodiments fall within the scope of the present invention and conform to the spirit of the present invention. As detailed descriptions about operations and technical features of the third and fourth exemplary embodiments are similar to the exemplary embodiments described above, the detailed descriptions are omitted here for the sake of brevity. However, those skilled in the art should be readily able to utilize the control signal generated by the signal generating circuit to protect the storage apparatus from unexpected damage after the teachings of the present invention. Thus, any technique that utilizes the signal level switching of the control signal of the controller while the power is shut down should be considered as falling within the scope of the present invention.

Reference in the specification to “one exemplary embodiment” or “an exemplary embodiment” means that a particular feature, structure, or characteristic described in connection with the exemplary embodiment is included in at least an implementation. The appearances of the phrase “in one exemplary embodiment” in various places in the specification are not necessarily all referring to the same exemplary embodiment. Thus, although exemplary embodiments have been described in language specific to structural features and/or methodological acts, it is to be understood that claimed subject matter may not be limited to the specific features or acts described. Rather, the specific features and acts are disclosed as sample forms of implementing the claimed subject matter.

Those skilled in the art will readily observe that numerous modifications and alterations of the device and method may be made while retaining the teachings of the invention.

What is claimed is:

1. A signal generating circuit, for generating a control signal in order to control operations of at least one of a controller and at least one storage unit controlled by the controller in a storage apparatus, the signal generating circuit comprising:
a voltage inputting unit, coupled to a power supplying terminal, for generating a voltage to be detected according to a voltage level of supply power received at the power supplying terminal; and
a voltage detecting unit, having an input terminal and an output terminal, the input terminal coupled to the voltage inputting unit and the output terminal coupled to at least one of respective control terminals of the controller and the storage unit, for comparing a predetermined voltage threshold with the voltage to be detected so as to generate the control signal, wherein the voltage detecting unit generates the control signal having a first logic level so that the controller is unable to perform write operations upon the storage unit when the voltage to be detected is lower than the predetermined voltage threshold, and the voltage detecting unit generates the control signal having a second logic level so that the controller is able to perform write operations upon the storage unit when the voltage to be detected is not lower than the predetermined voltage threshold.

2. The signal generating circuit of claim 1, wherein the output terminal of the voltage detecting unit is coupled to a reset control terminal of the controller, and the controller is reset and unable to perform write operations upon the storage unit when the control signal generated by the voltage detecting unit has the first logic level.

3. The signal generating circuit of claim 2, wherein the output terminal of the voltage detecting unit is further coupled to a write protection terminal of the storage unit, and when the control signal generated by the voltage detecting unit has the first logic level, the storage unit is under write protection so that the controller is unable to perform write operations upon the storage unit.

4. The signal generating circuit of claim 1, wherein the output terminal of the voltage detecting unit is further coupled to a write protection terminal of the storage unit, and when the control signal generated by the voltage detecting unit has the first logic level, the storage unit is under write protection so that the controller is unable to perform write operations upon the storage unit.

5. The signal generating circuit of claim 1, wherein a voltage level of the voltage to be detected is substantially equal to the voltage level of the supply power.

6. The signal generating circuit of claim 1, wherein the voltage inputting unit comprises:
a resistor, having one terminal coupled to the power supplying terminal and another terminal coupled to the input terminal of the voltage detecting unit; and
a capacitor, having one terminal coupled to the input terminal of the voltage detecting unit and another terminal coupled to a ground terminal.

7. The signal generating circuit of claim 1, wherein the storage apparatus is a solid state drive (SSD).

8. The signal generating circuit of claim 1, wherein the storage unit is a flash memory and the controller is a flash memory controller.

9. A storage apparatus, comprising:
at least one storage unit, for storing data;
a controller, coupled to the storage unit, for performing write and read operations upon the storage unit; and
a signal generating circuit, for generating a control signal to control operations of at least one of the controller and the storage unit, the signal generating circuit comprising:
a voltage inputting unit, coupled to a power supplying terminal, for generating a voltage to be detected according to a voltage level of supply power received at the power supplying terminal; and
a voltage detecting unit, having an input terminal and an output terminal, the input terminal coupled to the voltage inputting unit and the output terminal coupled to at least one of respective control terminals of the controller and the storage unit, for comparing a predetermined voltage threshold with the voltage to be detected so as to generate the control signal, wherein the voltage detecting unit generates the control signal having a first logic level so that the controller is unable to perform write operations upon the storage unit when the voltage to be detected is lower than the predetermined voltage threshold, and the voltage detecting unit generates the control signal having a second logic level so that the controller is able to perform write operations upon the storage unit when the voltage to be detected is not lower than the predetermined voltage threshold.

10. The storage apparatus of claim 9, wherein the output terminal of the voltage detecting unit is coupled to a reset control terminal of the controller, and the controller is reset and unable to perform write operations upon the storage unit when the control signal generated by the voltage detecting unit has the first logic level.

11. The storage apparatus of claim 10, wherein the output terminal of the voltage detecting unit is further coupled to a write protection terminal of the storage unit, and when the control signal generated by the voltage detecting unit has the first logic level, the storage unit is under write protection so that the controller is unable to perform write operations upon the storage unit.

12. The storage apparatus of claim 9, wherein the output terminal of the voltage detecting unit is further coupled to a write protection terminal of the storage unit, and when the control signal generated by the voltage detecting unit has the first logic level, the storage unit is under write protection so that the controller is unable to perform write operations upon the storage unit.

13. The storage apparatus of claim 9, wherein a voltage level of the voltage to be detected is substantially equal to the voltage level of the supply power.

14. The storage apparatus of claim 9, wherein the voltage inputting unit comprises:
a resistor, having one terminal coupled to the power supplying terminal and another terminal coupled to the input terminal of the voltage detecting unit; and
a capacitor, having one terminal coupled to the input terminal of the voltage detecting unit and another coupled to a ground terminal.

15. The storage apparatus of claim 9, being a solid state drive (SSD).

16. The storage apparatus of claim 9, wherein the storage unit is a flash memory and the controller is a flash memory controller.
